(19) United States
(12) Patent Application Publication
(10) Pub. No.: US 2014/0256097 A1
(43) Pub. Date: Sep. 11, 2014

(54) METHODS FOR FORMING INTEGRATED CIRCUIT SYSTEMS EMPLOYING FLUORINE DOPING

(71) Applicant: GLOBALFOUNDRIES INC., Grand Cayman (KY)

(72) Inventors: Ran Yan, Dresden (DE); Nicolas Sassiat, Dresden (DE); Jan Hoentschel, Dresden (DE); Torben Balzer, Dresden (DE)

(73) Assignee: GLOBALFOUNDRIES INC., Grand Cayman (KY)

(21) Appl. No.: 13/785,557

(22) Filed: Mar. 5, 2013

(51) Int. Cl. H01L 21/8238

(52) U.S. Cl. CPC H01L 21/823814
USPC 438/230; 438/303

(57) ABSTRACT

A method for forming a semiconductor device is provided which includes providing a gate structure in an active region of a semiconductor substrate, wherein the gate structure includes a gate insulating layer having a high-k material, a gate metal layer and a gate electrode layer, forming sidewall spacers adjacent to the gate structure and, thereafter, performing a fluorine implantation process. Also a method for forming a CMOS integrated circuit structure is provided which includes providing a semiconductor substrate with a first active region and a second active region, forming a first gate structure in the first active region and a second gate structure in the second active region, wherein each gate structure includes a gate insulating layer having a high-k material, a gate metal layer and a gate electrode layer, forming sidewall spacers adjacent to each of the first and second gate structures and, thereafter, performing a fluorine implantation process.

### BACKGROUND OF THE INVENTION

1. Field of the Invention

The present invention relates generally to integrated circuits, and, more particularly, to methods for forming integrated circuits employing fluorine implantation.

2. Description of the Related Art

The majority of present-day integrated circuits (ICs) are implemented by using a plurality of interconnected field effect transistors (FETS), also called metal oxide semiconductor field effect transistors (MOSFETS) or simply MOS transistors. Typically, present-day integrated circuits are implemented by millions of MOS transistors which are formed on a chip having a given surface area.

In MOS transistors, a current flow through a channel formed between the source and drain of a MOS transistor is controlled via a gate which is typically disposed over the channel region, independent from whether a PMOS transistor or an NMOS transistor is considered. For controlling a MOS transistor, a voltage is applied to the gate electrode of the gate and a current flows through the channel when the applied voltage is greater than a threshold voltage, which nontrivially depends on properties of a transistor, such as size, material etc.

In efforts to build integrated circuits with a greater number of transistors and faster semiconductor devices, developments in semiconductor technologies have aimed at ultra large scale integration (ULSI), which resulted in ICs of ever-decreasing size and, therefore, of MOS transistors having reduced sizes. In present-day semiconductor technology, the minimum feature sizes of microelectronic devices have been approaching the deep submicron regime so as to continually meet the demand for faster and lower power microprocessors and digital circuits and generally for semiconductor device structures having improved high energy efficiency. In general, a critical dimension (CD) is represented by a width or length dimension of a line or space that has been identified as critical to the device under fabrication for operating properly and, furthermore, which dimension determines the device performance.

As a result, the continued increase in performance of ICs and the ongoing reduction of IC dimensions to smaller scales has increased the integration density of IC structures. However, as semiconductor devices and device features have become smaller and more advanced, conventional fabrication techniques have been pushed to their limits, challenging their abilities to produce finely defined features at the presently required scales. Consequently, developers are faced with more and more scaling limitations which arise as semiconductors continue to decrease in size.

Normally, IC structures provided on a microchip are realized by millions of individual semiconductor devices such as PMOS transistors or NMOS transistors. As transistor performance depends crucially on several factors, for example, on the threshold voltage, it is easy to see that it is highly nontrivial to control a chip's performance, which requires keeping many parameters of individual transistors under control, especially for strongly-scaled semiconductor devices. For example, deviations in the threshold voltage of transistor structures across a semiconductor chip strongly affect the reliability of the whole chip under fabrication. In order to ascertain a reliable controllability of transistor devices across a chip, a well-defined adjustment of the threshold voltage for each transistor has to be maintained to a high degree of accuracy. As the threshold voltage alone already depends on many factors, it is necessary to provide a controlled process flow for fabricating transistor devices which reliably meet all these factors.

It is generally known that the high-k metal gate (HKMG) stack in gate-first process integrations is very sensitive to any processing performed during various process flows. Especially at the high-k/metal gate/silicon channel interfaces at the edge of transistor devices, the stack configurations are very sensitive to accumulation of oxygen. The accumulation of oxygen may change charging at the work function adjusting metal layer and, particularly at the edges along the gate. This is not only very critical in length direction of a semiconductor device structure, but also in width direction where, due to the topographies of active regions and STI regions, a polysilicon line rounding may occur on the interface from an active region to shallow trench isolation (STI) corners delineating active regions. STI represents an IC feature that prevents electrical current leakage between semiconductor devices formed in adjacent active regions. Due to incorporation of oxygen, charging at these interfaces may change and, accordingly, a shift in the work function will be induced, resulting in changes of the threshold voltage. This effect depends on the width of a semiconductor device. With smaller width dimensions, greater changes in the threshold voltage may occur.

FIG. 1 illustrates very schematically a relation between a width of a semiconductor substrate (W in nm) plotted against the linear threshold voltage (Vt_{Lin}). As shown in FIG. 1, scaling down transistor devices in their width dimensions induces a roll-up of Vt_{Lin}, which is often referred to as “Vt_{Lin} versus W effect.” By way of example, when starting from a width dimension of around 900 nm, a Vt_{Lin} roll-up of roughly around 0.1 V may be expected for scaling down to 72 nm.

In current process flows, it is, therefore, critical to avoid processes that incorporate oxygen after the high-k metal gate stack is formed so as to reduce the incorporation of oxygen and to diminish the Vt_{Lin} versus W effect.

It is, therefore, desirable to provide technologies at smaller technology nodes which enable reducing variations in the threshold voltage of semiconductor devices.

The present disclosure provides a method for forming a semiconductor device and a method for forming a CMOS integrated circuit structure resulting in accordingly fabricated devices and device structures.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

According to some aspects of the present disclosure, methods are provided which comprise forming a high-k metal gate structure on a surface of a semiconductor substrate and performing a fluorine implantation process after having formed sidewall spacers adjacent to the high-k metal gate structure.

According to an illustrative embodiment of the present disclosure, a method for forming a semiconductor device is provided, the method including providing a gate structure in an active region of a semiconductor substrate, the gate structure including a gate insulating layer having a high-k material, a gate metal layer and a gate electrode layer, forming sidewall spacers adjacent to the gate structure and, thereafter, performing a fluorine implantation process.

According to another illustrative embodiment of the present disclosure, a method for forming a CMOS integrated circuit structure is provided, the method including providing a semiconductor substrate with a first active region and a second active region, forming a first gate structure in the first active region and a second gate structure in the second active region, each gate structure including a gate insulating layer having a high-k material, a gate metal layer and a gate electrode layer, forming sidewall spacers adjacent to each of the first and second gate structures and, thereafter, performing a fluorine implantation process.

### BRIEF DESCRIPTION OF THE DRAWINGS

The disclosure may be understood by reference to the following description taken in conjunction with the accompanying drawings, in which like reference numerals identify like elements, and in which:

FIG. 1 schematically illustrates a relation between a width of a conventional transistor device and the linear threshold voltage;

FIGS. 2 and 3 schematically illustrate, in a cross-sectional view, an exemplary process flow according to an embodiment of the present disclosure; and

FIG. 4 schematically illustrates a graphical relation between a width dimension of transistor devices according to embodiments of the present disclosure and the linear threshold voltage of respective transistor devices.

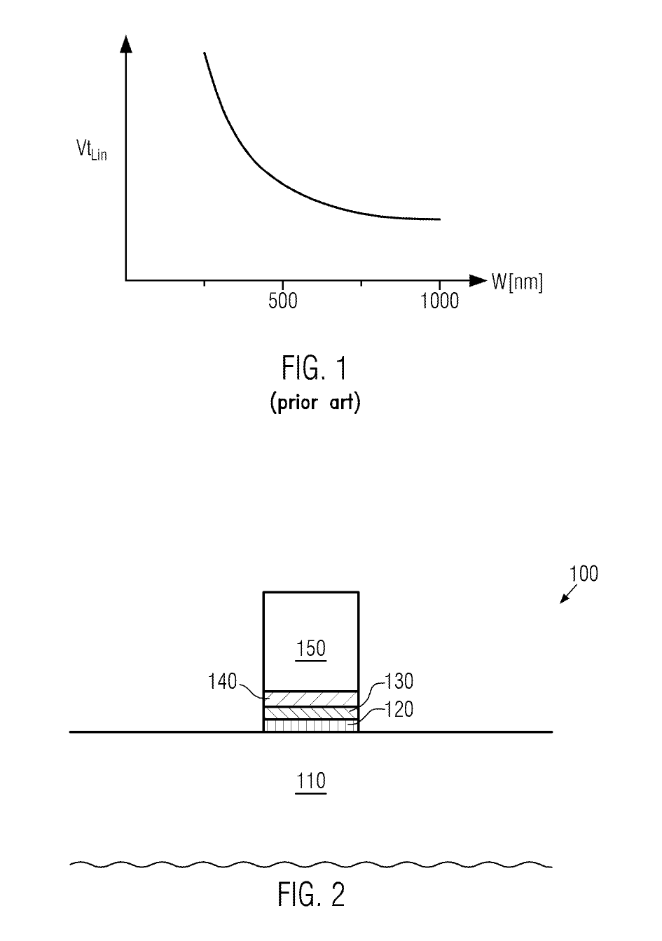

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Integrated circuits (ICs) may be designed with millions of transistors. Many ICs are designed using metal oxide semiconductor (MOS) transistors, also known as field effect transistors (FETs) or MOSFETs. Although the term “MOS transistor” properly refers to a device having a metal gate electrode and an oxide gate insulator, that term will be used throughout to refer to any semiconductor device that includes a conductive gate electrode (whether metal or other conductive material) that is positioned over a gate insulator (whether oxide or other insulator) which, in turn, is positioned over a semiconductor substrate. The person skilled in the art understands that MOS transistors may be fabricated as P-channel MOS transistors or PMOS transistors and as N-channel transistors or NMOS transistors, and both may be fabricated with or without mobility enhancing stressor features or strain-inducing features. The person skilled in the art understands that stress and strain may be described with regard to a tensile modulus. A circuit designer may mix and match device types, using PMOS and NMOS transistors, stressed and unstressed, to take advantage of the best characteristics of each device type as they best suit the circuit being designed.

In describing the following figures, semiconductor device structures and methods for forming a semiconductor device in accordance with various exemplary embodiments of the present disclosure will be illustrated. The described process steps, procedures and materials are to be considered only as exemplary embodiments designed to illustrate to one of ordinary skill in the art, methods for practicing the invention. However, it is to be understood that the invention is not to be limited to these exemplary embodiments. Illustrated portions of semiconductor devices and semiconductor device structures may include only a single MOS structure, although those skilled in the art will recognize that actual implementations of integrated circuits may include a large number of such structures. Various steps in the manufacture of semiconductor devices and semiconductor device structures are well known and so, in the interest of brevity, many conventional steps will only be mentioned briefly herein, or will be omitted entirely without providing the well-known process details.

FIG. 2 illustrates a semiconductor device structure 100 during a process for fabricating a semiconductor device according to an illustrative embodiment of the present disclosure. The semiconductor device structure 100 is formed on a semiconductor substrate 110 and comprises a gate stack formed above a surface of the semiconductor substrate 110.

The person skilled in the art will appreciate that the semiconductor substrate 110 may be provided by silicon, silicon admixed with germanium, or silicon admixed with other elements as is common in the semiconductor industry, and for convenience will hereinafter be referred to simply as either a semiconductor or silicon substrate. The substrate may be a bulk silicon wafer or a silicon-on-insulator (SOI) structure. In an SOI structure, the semiconductor substrate 110 is a thin later of monocrystalline semiconductor material supported by an insulating layer which, in turn, is supported by a supporting substrate.

The gate stack may comprise a high-k/metal gate stack configuration formed on the semiconductor substrate 110. The person skilled in the art appreciates that a high-k material may be represented, for example, by HfO₂ (hafnium oxide), HfSiO₂, ZrO₂ or ZrSiO₂ or HfSiON (hafnium-silicon oxynitride) or a combination of two or more thereof. In general, a high-k material may be given by a material having a dielectric constant greater than 4.

A gate metal may be provided on the high-k material. The gate metal may be given by a metal, such as Ru, a metal alloy such as TiNi, a metal nitride such as TaN, TaSiN, TiN, HfN, or a metal oxide, such as RuO₂, hafnium oxide or tantalum oxide, or any combination thereof. The person skilled in the art will appreciate that the work function of the metal gate material may be further adjusted by including materials like Al, La and the like.

As shown in FIG. 2, the gate stack according to the illustrated embodiment may comprise a high-k stack configuration which is given by a bilayer stack, such as a high-k layer 120 formed on a surface of the semiconductor substrate 110 and a high-k layer 130 disposed on the high-k layer 120. According an illustrative example herein, the high-k layer 120 may, for example, include HfO₂ and the high-k layer 130 may, for example, include HfSiON. According to an alternative embodiment herein, the high-k layer 120 may comprise HfSiON and the high-k layer 130 may comprise HfO₂. According to another alternative embodiment, the layer 120 may comprise a silicon-based dielectric material and the layer 130 may comprise a high-k dielectric material. A metal gate layer 140 is disposed on the high-k bilayer stack 120 and 130 as shown in FIG. 2. The metal gate layer 140 may be comprised of one layer or may include two or more layers.

In the embodiment as illustrated in FIG. 2, a gate electrode layer 150 is formed on the metal gate layer 140. According to an illustrative example herein, the gate electrode layer 150 may be comprised of a polysilicon material. According to alternative embodiments herein, the gate electrode layer 150 may comprise a metal material.

Although not explicitly illustrated in FIG. 2, it is also possible that an additional liner may be disposed under the high-k layer 120. The additional liner may be embedded in or formed above the surface of the semiconductor substrate 110. The additional liner layer may comprise a strain-inducing material for improving the mobility of charge carriers in a channel region of the semiconductor substrate 110 under the gate structure. According to an alternative embodiment, the liner layer may comprise silicon oxide SiO₂.

The semiconductor device structure 100 as illustrated in FIG. 2 may be obtained by a suitable process flow, such as by suitable depositing, patterning and etching steps which may involve depositing a high-k and metal gate, respectively, material layer and forming a masking pattern over the deposited layer and performing an etching step through the masking pattern followed by removing the masking pattern. The person skilled in the art will appreciate that the gate structure of the semiconductor device structure 100 as illustrated in FIG. 2 may be obtained by repeating according processing steps as schematically discussed above.

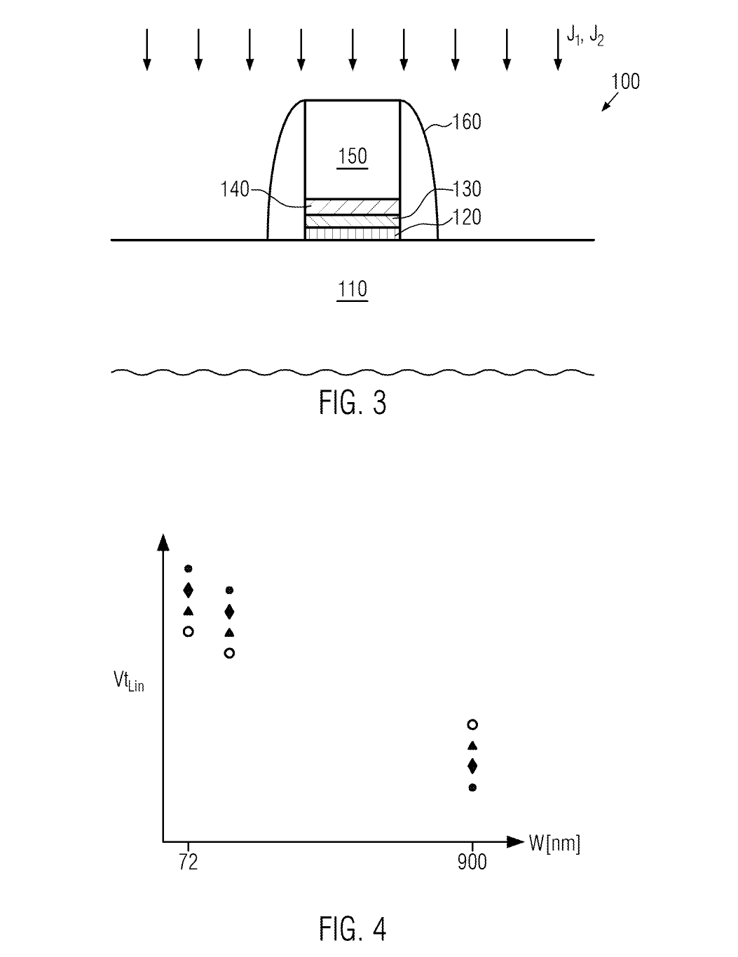

FIG. 3 illustrates the semiconductor device structure 100 during subsequent processing according to an illustrative embodiment of the present disclosure. A sidewall spacer structure 160 is formed adjacent to the gate structure so as to cover sidewalls of the various layers representing the gate structure. Although FIG. 3 only illustrates a sidewall spacer structure 160 consisting of one sidewall spacer, no limitation is posed to the present disclosure and two or more sidewall spacers may be provided in alternative embodiments. The person skilled in the art will appreciate that the sidewall spacer structure 160 may be comprised of two or more sidewall spacers and may further comprise a liner (not illustrated) between the sidewall spacer structure 160 and the gate structure for encapsulating the gate structure and, in particular, the high-k structure 120, 130.

The person skilled in the art will appreciate that the semiconductor device structure 100 as illustrated in FIG. 3 may be obtained by depositing one or more sidewall spacer forming materials over the semiconductor device structure 100 of FIG. 2 and performing appropriate etching processes in order to form the sidewall spacer structure 160 as shown in FIG. 3 as known in the art.

Next, as illustrated in FIG. 3, implantation processes may be performed. According to the illustrative embodiment as shown in FIG. 3, the implantation processes may comprise implantation processes J1 and J2. The implantation processes J1 and J2 may be sequential in nature so that the implantation processes J1 and J2 need not occur at the same time. A person skilled in the art will appreciate that one of the implantation processes J1 and J2 may be a fluorine implantation process. In an illustrative example herein, the fluorine implantation process may comprise a blanket deposition step.

According to an illustrative example of the embodiment illustrated in FIG. 3, the fluorine implantation process may be performed with a fluorine implant dose which is on the order of about 1E¹⁵ to about 5E¹⁵. According to an illustrative example herein, the fluorine implant dose may be on the order of about 3E¹⁵. The person skilled in the art will appreciate that the implant dose may be measured in units of atoms/cm². The implantation angle may range from about 0-75 degrees. According to an illustrative example of the embodiment as shown in FIG. 3, the implantation angle may be about 0 degrees.

The person skilled in the art will appreciate that one implantation process of the implantation processes J1 and J2 may be at least one of a source/drain extension implantation process and a halo region implantation process and a source/drain implantation process such that at least one of source/drain extension regions and halo regions and source/drain regions may be formed. According to an illustrative embodiment, the source/drain extension region implantation process and the source/drain implantation process may be configured to form N-type source/drain extension regions (not illustrated) and source/drain regions (not illustrated) adjacent to the gate structure as shown in FIG. 3 and in alignment with the sidewall spacer structure 160.

Subsequent to the processing described above with regard to FIG. 3, an optional annealing process (not illustrated) may be performed. According to some illustrative examples herein, the annealing process may comprise annealing at temperatures of at least around 400° C. to about 1100° C. and according to some illustrative examples in a range between about 450-1050° C. or in a range between about 800-1000° C. The annealing process may be performed after the fluorine implantation process as described above. The person skilled in the art will appreciate that the annealing process may be performed in order to activate the implanted species or to facilitate diffusion of fluorine atoms such that fluorine may consume charged oxygen vacancies generated due to earlier processes. The person skilled in the art will appreciate that annealing processes may be configured so as to respect constraints imposed by thermal budget considerations. The person skilled in the art will appreciate that the annealing time used for applying the annealing temperature may be chosen longer when applying lower annealing temperatures. Herein the expressions “longer” and “lower” are relative expressions with regard to annealing temperatures of the above given ranges and their associated annealing times.

The embodiments described with regard to FIGS. 2 and 3 are presented by only explicitly describing a single semiconductor device structure. This does not pose any limitation on the present disclosure. The person skilled in the art will appreciate that according considerations may as well apply to structures involving two or more semiconductor devices such as one or more PMOS devices and one or more NMOS devices and one or more CMOS devices. When processing two or more semiconductor devices, processing may be performed simultaneously or sequentially when appropriate masking steps are considered.

FIG. 4 illustrates a relation of semiconductor devices fabricated according to several illustrative embodiments of the present disclosure plotted against the linear threshold voltage Vt_{Lin}. It is noted that the illustration in FIG. 4 is only schematic and no preferred scaling is intended to be inferred by FIG. 4. The graph in FIG. 4 is only provided to illustrate a general relation between a width dimension of a semiconductor device according to illustrative embodiments with the linear threshold voltage Vt_{Lin}.

In FIG. 4, semiconductor devices which are not subjected to a fluorine implantation process are denoted by solid bullets. Semiconductor devices which are denoted by a solid diamond symbol were subjected to a fluorine implantation process with a fluorine implant dose of about 1E′⁵. Semiconductor devices which are denoted by a solid triangle symbol were subjected to a fluorine implantation process with a fluorine implant dose of about 2E¹⁵. Semiconductor devices which are denoted by circle bullets were subjected to a fluorine implantation process with a fluorine implant dose of about 3E¹⁵.

FIG. 4 illustrates the roll-up of the linear threshold voltage for semiconductor devices scaled down from 900 nm to 72 nm in the width dimension which is not subjected to a fluorine implantation process. As it is apparent from the illustration in FIG. 4, when increasing the implant dose of fluorine to from 0 to 3E¹⁵, a considerable reduction of the roll-up of the linear threshold voltage Vt_{Lin} may be obtained.

The person skilled in the art will appreciate that the present disclosure provides semiconductor devices showing improved control behavior of the threshold voltage when being scaled down. The person skilled in the art will appreciate that a roll-up of the threshold voltage may be reduced in embodiments of the present disclosure down to a deviation of less than 5%. According to some illustrative embodiments, a deviation may be even less than 3.5%. According to an illustrative example of the present disclosure, a deviation in the linear threshold voltage given by a difference of the linear threshold voltage between a 900 nm device width and a 72 nm device width may be reduced by 0.04 V as compared to the same process with no fluorine implantation being performed.

The present disclosure provides a fluorine implantation step after spacer formation that allows reducing oxygen incorporation at the edges along high-k/metal gate stacks in the width direction.

The person skilled in the art will appreciate that the main advantages of the present disclosure comprise a very simple process change which results in an increased yield with a low Vt_{Lin} versus W roll-up and increased performance of the fabricated semiconductor devices.

The person skilled in the art will appreciate that the gate stacks according to embodiments of the present disclosure may be protected by sidewall spacer structures such as liners and/or spacer zero and spacer one structures according to illustrative examples, while the fluorine implantation step allows a consumption of charged oxygen vacancies created by any processing steps before in the process flow without involving any complicated mechanism to improve the STI/active area topography which becomes complicated and complex at very low scales.

The present disclosure provides a method for forming a semiconductor device. According to an illustrative embodiment, the method includes providing a gate structure in an active region of a semiconductor substrate, wherein the gate structure includes a gate insulating layer having a high-k material, a gate metal layer and a gate electrode layer. The method further includes forming sidewall spacers adjacent to the gate structure and, thereafter, performing a fluorine implantation process.

The present disclosure also provides a method for forming a CMOS integrated circuit structure. According to illustrative embodiments, the method includes providing a semiconductor substrate with a first active region and a second active region, forming a first gate structure in the first active region and a second gate structure in the second active region, wherein each gate structure includes a gate insulating layer having a high-k material, a gate metal layer and a gate electrode layer. The method further includes forming sidewall spacers adjacent to each of the first and second gate structures and, thereafter, performing a fluorine implantation process.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

1. A method for forming a semiconductor device, comprising:
providing a gate structure in an active region of a semiconductor substrate, the gate structure comprising a gate insulating layer having a high-k material, a gate metal layer and a gate electrode layer, wherein said gate metal layer is positioned on the gate insulating layer and the gate electrode layer is positioned on the gate metal layer;
forming sidewall spacers adjacent to the gate structure; and thereafter
performing a fluorine implantation process.

2. The method of claim 1, wherein said fluorine implantation process comprises a blanket deposition step.

3. The method of claim 1, wherein said fluorine implantation process is performed with a fluorine implant dose which is on the order of about 1E15 to about 5E15 atoms/cm².

4. The method of claim 1, wherein said fluorine implantation process is performed with a fluorine implant dose which is on the order of about 3E15 atoms/cm².

5. The method of claim 1, wherein said gate insulating layer has a bilayer stack configuration comprising a hafnium-silicon oxynitride layer and a hafnium oxide layer.

6. The method of claim 5, wherein said gate metal layer comprises TiN disposed on the hafnium-silicon oxynitride layer.

7. The method of claim 6, wherein a silicon oxide interlayer is formed between said semiconductor substrate and said high-k material.

8. The method of claim 1, wherein forming sidewall spacers comprises forming encapsulation liners for encapsulating said gate insulating layer such that sidewalls of said high-k material are covered by said encapsulation liners.

9. The method of claim 1, further comprising performing an anneal process after said fluorine implantation process.

10. The method of claim 9, wherein said anneal process comprises annealing at temperatures in a range from about 450-1050° C.

11. The method of claim 1, further comprising forming N-type source and drain regions in alignment with said sidewall spacers.

12. A method for forming a CMOS integrated circuit structure, comprising:
providing a semiconductor substrate with a first active region and a second active region;
forming a first gate structure in said first active region and a second gate structure in said second active region, each gate structure comprising a gate insulating layer having a high-k material, a gate metal layer and a gate electrode layer, wherein said gate metal layer is positioned on the gate insulating layer and the gate electrode layer is positioned on the gate metal layer;
forming sidewall spacers adjacent to each of said first and second gate structures; and thereafter
performing a fluorine implantation process.

13. The method of claim 12, wherein said fluorine implantation process comprises a blanket deposition step.

14. The method of claim 12, wherein said fluorine implantation process is performed with a fluorine implant dose which is on the order of about 1E15 to about 5E15 atoms/cm².

15. The method of claim 12, wherein said fluorine implantation process is performed with a fluorine implant dose which is on the order of 3E15 atoms/cm².

16. The method of claim 12, wherein said gate insulating layer has a bilayer stack configuration comprising a hafnium-silicon oxynitride layer and a hafnium oxide layer.

17. The method of claim 16, wherein said gate metal layer of said first gate structure comprises TiN disposed on said hafnium-silicon oxynitride layer and said gate metal layer of said second gate structure comprises one of TiC and TiN disposed on said hafnium-silicon oxynitride layer.

18. The method of claim 17, wherein a silicon oxide interlayer is formed between said semiconductor substrate and said high-k material of either gate structure.

19. The method of claim 12, wherein forming sidewall spacers comprises forming encapsulation liners for encapsulating said gate insulating layers of either gate structure such that sidewalls of said high-k material of either gate structure are covered by said encapsulation liners.

20. The method of claim 12, further comprising performing an anneal process after said fluorine implantation process.
